(19) United States
(12) Patent Application Publication
(10) Pub. No.: US 2026/0190449 A1
(43) Pub. Date: Jul. 2, 2026

(54) SEMICONDUCTOR DEVICE UTILIZING BIPOLAR DIPOLE METAL OXIDES FOR GE-BASED CMOS AND MANUFACTURING METHOD THEREOF

(71) Applicant: TAIWAN SEMICONDUCTOR MANUFACTURING COMPANY, LTD., Hsinchu (TW)

(72) Inventors: Cheng-Ming LIN, Kaohsiung City (TW); Yu-Hsien CHIANG, Hsinchu City (TW); Wei-Yen WOON, Taoyuan City (TW); Szuya LIAO, Hsinchu County (TW)

(73) Assignee: TAIWAN SEMICONDUCTOR MANUFACTURING COMPANY, LTD., Hsinchu (TW)

(21) Appl. No.: 19/008,377

(22) Filed: Jan. 2, 2025

(51) Int. Cl. H10D 84/01; H10D 84/85

(52) U.S. Cl. CPC H10D 84/0181; H10D 84/0167; H10D 84/017; H10D 84/851; H10D 84/856

(57) ABSTRACT

A method includes using metal oxide as a bipolar dipole material to enable the use of Ge-based channel CMOS technology with a dipole-first scheme for VT control. Specifically, a dipole-first scheme can provide a low-temperature approach for Ge-based CMOS. Additionally, the dipole-first scheme can eliminate additional drive-in and strip processes.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic view of a semiconductor structure in accordance with some embodiments of the present disclosure.

FIG. 1B illustrates a schematic cross-sectional view of a gate structure in a semiconductor structure in accordance with some embodiments of the present disclosure.

FIGS. 2-12B illustrate schematic cross-sectional views of intermediate stages in the formation of a semiconductor structure in accordance with some embodiments.

FIGS. 13A-22 illustrate schematic cross-sectional views of intermediate stages in the formation of a semiconductor structure in accordance with some embodiments.

FIGS. 23-25 illustrate schematic cross-sectional views of semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

This disclosure can address challenges related to the dipole drive-in method for CMOS technology, particularly when using high mobility materials like Ge-based (germanium-based) channels in sequential complementary field-effect transistor (CFET) technology. The drive-in method may require high temperatures (above 600° C.), which are unsuitable for Ge-based CMOS. Additionally, the high temperatures of the drive-in method can induce additional degradation at the high-k/Ge interface, compromising the performance of the transistor. Furthermore, the dipole-first scheme may lack flexibility in achieving effective threshold voltage (VT) control.

Therefore, the present disclosure in various embodiments provides a method by using metal oxide as a bipolar dipole material to enable the use of Ge-based channel CMOS technology with an effective dipole-first scheme for VT control. Specifically, a dipole-first scheme can provide a low-temperature approach suitable for Ge-based CMOS. Additionally, the dipole-first scheme can eliminate additional drive-in and strip processes. In some embodiments, this disclosure can utilize strained GeSi and GeSn channels, which can provide a high-performance to CMOS devices.

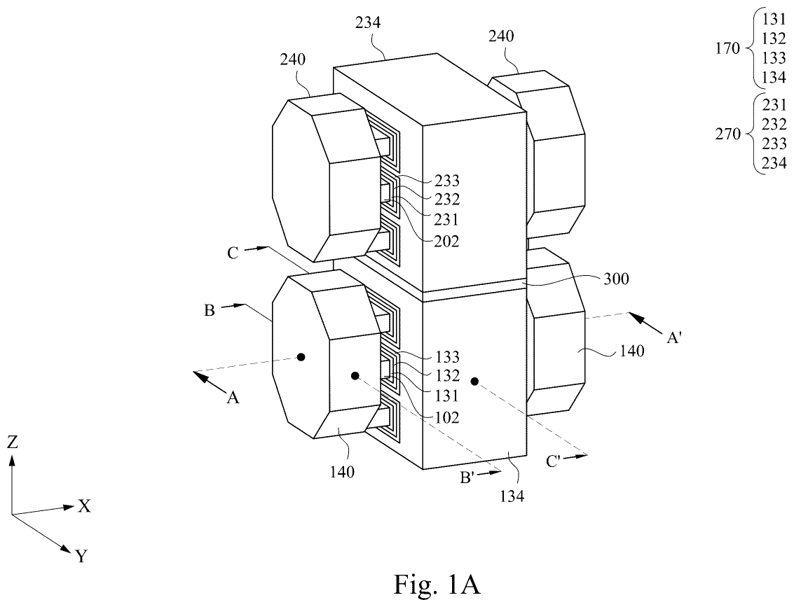

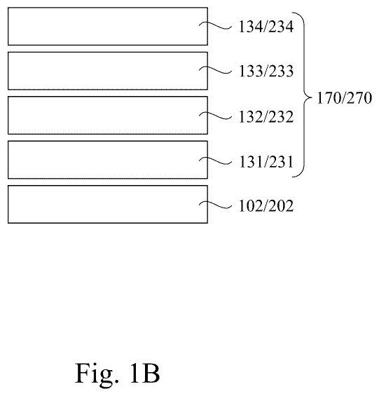

Reference is made to FIGS. 1A and 1B. FIG. 1A illustrates a schematic view of a semiconductor structure in accordance with some embodiments of the present disclosure. FIG. 1B illustrates a schematic cross-sectional view of a gate structure in a semiconductor structure in accordance with some embodiments of the present disclosure. FIG. 1A further illustrates reference cross-sections that are used in later figures. Cross-section A-A′ is parallel to a longitudinal axis of the semiconductor nanostructures 102/202 of a CFET and in a direction of, for example, a current flow between the source/drain regions 140/240 of the CFET. Cross-section B-B′ is parallel to a longitudinal axis of the metal gate structure 170/270 of the CFET. Subsequent figures refer to these reference cross-sections for clarity.

Reference is made to FIG. 1A. FIG. 1A illustrates an example of a CFET schematic, in accordance with some embodiments. FIG. 1A is a three-dimensional view, where some features of the CFETs are omitted for illustration clarity. The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures (including lower semiconductor nanostructures 102 and upper semiconductor nanostructures 202), where the semiconductor nanostructures 102/202 act as channel regions for the nanostructure-FETs. The semiconductor nanostructures 102/202 may be nanosheets, nanowires, or the like. The lower semiconductor nanostructures 102 are for a lower nanostructure-FET, and the upper semiconductor nanostructures 202 are for an upper nanostructure-FET. A channel isolation material (e.g., bonding structure 300 as shown FIG. 22) may be used to separate and electrically isolate the upper semiconductor nanostructures 202 from the lower semiconductor nanostructures 102. Alternatively, the gate electrode layers 234 may optionally be separated from the gate electrode layers 134 by the isolation layer 105. Alternatively, the gate electrode layers 234 may be coupled to the gate electrode layers 134.

As shown in FIGS. 1A and 1B, each of the nanostructure-FETs include gate structure (e.g., metal gate structure 170/270). The metal gate structure 170 may include an oxide layer 131, a dipole layer 132, a gate dielectric layer 133, and a gate electrode layer 134, and the metal gate structure 270 may include an oxide layer 231, a dipole layer 232, a gate dielectric layer 233, and a gate electrode layer 234. Specifically, the oxide layer 131 can be along top surfaces, sidewalls, and bottom surfaces of the semiconductor nanostructure 102, and the oxide layer 231 can be along top surfaces, sidewalls, and bottom surfaces of the semiconductor nanostructure 202. The dipole layer 132 can be over the oxide layer 131 and around the semiconductor nanostructure 102, and the dipole layer 232 can be over the oxide layer 231 and around the semiconductor nanostructure 202. The gate dielectric layer 133 can be over the dipole layers 132 and around the semiconductor nanostructure 102, and the gate dielectric layer 233 can be over the dipole layer 232 and around the semiconductor nanostructure 202. The gate electrode layer 134 can be over the gate dielectric layer 133 and around the semiconductor nanostructure 202, and the gate electrode layer 234 can be over the gate dielectric layer 233 and around the semiconductor nanostructure 202. Epitaxial source/drain regions 140 and epitaxial source/drain regions 240 can be disposed at opposing sides of the semiconductor nanostructures 102 and the semiconductor nanostructures 202. Source/drain region(s) 140/240 may refer to a source or a drain, individually or collectively dependent upon the context. Further, the upper epitaxial source/drain regions 240 may be separated from lower epitaxial source/drain regions 140 by one or more dielectric layers. The isolation features between channel regions, gates, and source/drain regions allow for vertically stacked transistors, thereby improving device density. Because of the vertically stacked nature of CFETs, the schematic may also be referred to as stacking transistors or folding transistors.

The gate structure 170/270 can control the electrostatic environment around the semiconductor nanostructures 102/202, which serve as the channel regions for the FETs. Therefore, the gate structure 170/270 can modulate the flow of current through the channels in response to applied voltages. In some embodiments, the oxide layer 131/231 can provide an interface between the semiconductor nanostructures 102/202 and the subsequent layers, acting as an insulating barrier that helps in reducing the number of interface traps that could affect carrier mobility. In some embodiments, the oxide layer 131/231 can set the initial oxygen concentration for subsequent dipole layer 132/232 formation. The oxygen gradient between the oxide layers 131/231 and the dipole layers 132/232 can determines the dipole effect, which is central to threshold voltage modulation.

The dipole layer 132/232 can create a dipole field that can help in tuning the threshold voltage (Vₜ) of the transistor. Specifically, the dipole layer can form a Dipole with the oxide Layer 131/231. The difference in oxygen concentration between the oxide layer 131/231 and the dipole layer 132/232 can form a P-dipole (in NFETs) or an N-dipole (in PFETs), creating a localized electric field, which impacts the electrostatic potential in the channel region (i.e., semiconductor nanostructure 102/202). By adjusting the oxygen areal density in the dipole layer 132/232 compared to the oxide layer 131/231, the dipole effect can be fine-tuned to provide effective threshold voltage control, ensuring that both NMOS and PMOS devices can operate with the desired electrical characteristics.

In some embodiments, a higher oxygen concentration in the oxide layer 131/231 compared to the dipole layer 132/232 can form a P-dipole, which is used in NFETs to lower the threshold voltage. Conversely, a lower oxygen concentration in the oxide layer 131/231 compared to the dipole layer 132/232 can form an N-dipole, which is used in PFETs to increase the threshold voltage. This interaction is what allows the stacked CFET configuration to achieve threshold voltage tuning for both upper and lower transistors within the gate-all-around (GAA) architecture, enhancing both power efficiency and device performance. By way of example but not limiting the present disclosure, the oxide layers 131/231 can be made from SiO₂ or SnO₂, depending on the material of the underlying semiconductor nanostructure 102/202. The dipole layers 132/232 can be made from metal oxides such as In₂O₃, CeO₂, Sc₂O₃, MgO, or combinations thereof. The dipole layers 132/232 can be made based on their oxygen areal density relative to the oxide layer 131/231 to create the dipole effect.

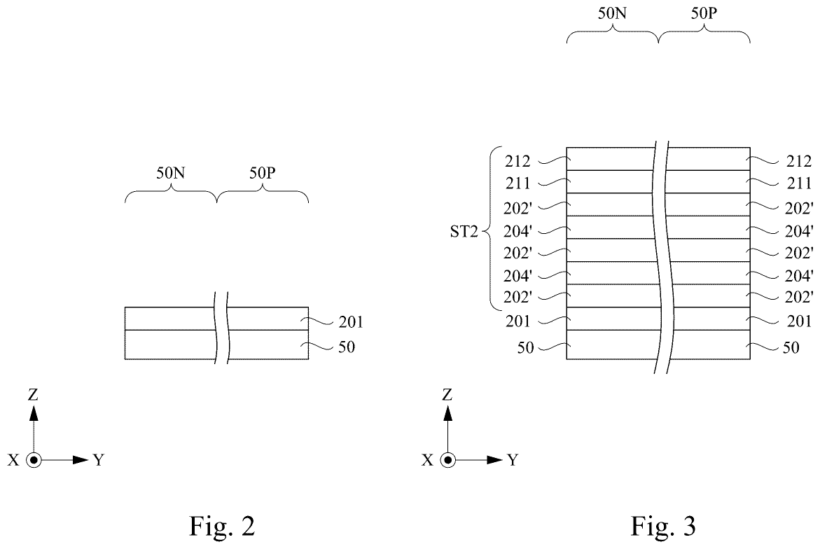

Reference is made to FIGS. 2-12B. FIGS. 2-12B illustrate schematic cross-sectional views of intermediate stages in the formation of a semiconductor structure in accordance with some embodiments. These cross-section views are along the gate's extension direction or a direction perpendicular to a lengthwise direction of a channel region of the semiconductor structure. It is understood that additional operations can be provided before, during, and after the processes shown by FIGS. 2-12B, and some of the operations described below can be replaced or eliminated, for additional embodiments of the method. The order of the operations/processes may be interchangeable.

Reference is made to FIG. 2. A buffer layer 201 can be formed over a substrate 50. As shown in FIG. 2, the substrate 50 can be provided, in accordance with some embodiments. The substrate 50 may be a semiconductor substrate, such as a bulk semiconductor, a semiconductor-on-insulator (SOI) substrate, or the like, which may be doped (e.g., with a p-type or an n-type dopant) or un-doped. The substrate 50 may be a wafer, such as a silicon wafer. An SOI substrate is a layer of a semiconductor material formed on an insulator layer. The insulator layer may be, for example, a buried oxide (BOX) layer, a silicon oxide layer, or the like. The insulator layer can be provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium tin (GeSn), gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 can have a first conductivity type device region 50N and a second conductivity type device region 50P. The first conductivity type device region 50N can be for forming n-type devices, such as NMOS transistors, e.g., n-type nanostructure-FETs, and the second conductivity type device region 50P can be for forming p-type devices, such as PMOS transistors, e.g., p-type nanostructure-FETs. The first conductivity type device region 50N may (or may not) be physically separated (not separately illustrated) from the second conductivity type device region 50P, and any number of device features (e.g., other active devices, doped regions, isolation structures, etc.) may be disposed between the first conductivity type device region 50N and the second conductivity type device region 50P. Although one first conductivity type device region 50N and one second conductivity type device region 50P are illustrated, any number of n-type regions 50N and p-type regions 50P may be provided. Subsequent figures describe processing steps that may be performed in either the n-type regions 50N or the p-type regions 50P unless otherwise noted.

In some embodiments, the buffer layer 201 can be made of a semiconductor material each be selected from the candidate semiconductor materials of the substrate 50. In some embodiments, the buffer layer 201 can include an element component as that in the channel region of the semiconductor device. In some embodiments, the buffer layer 201 can be the same as the semiconductor layers 204′.

Reference is made to FIG. 3. A multi-layer stack ST2 can be formed over the substrate 50, in accordance with some embodiments. The multi-layer stack ST2 can include alternating semiconductor layers 202′ and semiconductor layers 204′. The semiconductor layers 202′ are formed of a first semiconductor material, and the semiconductor layers 204′ are formed of a second semiconductor material. The semiconductor materials may each be selected from the candidate semiconductor materials of the substrate 50. In the illustrated embodiment, and as subsequently described in greater detail, the semiconductor layers 204′ will be removed and the semiconductor layers 202′ will patterned to form channel regions for the nanostructure-FETs in the first conductivity type device region 50N. The semiconductor material of the semiconductor layers 202′ may be a material suitable for n-type devices, such as silicon germanium (e.g., Ge₁₋ₓSiₓ, wherein x can be in a range from about 0.01 to 2), a III-V compound semiconductor, a II-VI compound semiconductor, or the like. The semiconductor layers 204′ can be dummy layers that will be removed in subsequent processing to expose top surfaces and bottom surfaces of the semiconductor layers 202′. The semiconductor material of the semiconductor layers 204′ can be a material that has a high etching selectivity from the etching of the semiconductor layers 202′, such as germanium (e.g., pure germanium or SiₓGe₁₋ₓ, wherein germanium atomic percentage concentration in the semiconductor layers 202′ may be greater than about 60%). In some embodiments, the semiconductor layer 202′ can have a thickness in a range from about 1 to 10 nm, such as about 1, 2, 3, 4, 5, 6, 7, 8, 9, or 10 nm.

The multi-layer stack ST2 can be illustrated as including two of the semiconductor layers 204′ and three of the semiconductor layers 202′. It should be appreciated that the multi-layer stack ST2 may include any number of the semiconductor layers 202′ and the semiconductor layers 204′. Each of the layers of the multi-layer stack ST2 may be grown by a process such as vapor phase epitaxy (VPE) or molecular beam epitaxy (MBE), deposited by a process such as chemical vapor deposition (CVD) or atomic layer deposition (ALD), or the like.

Subsequently, a cap layer 211 and a protective layer 212 can be formed over the multi-layer stack ST2. In some embodiments, the cap layer 211 can be made of a semiconductor material selected from the candidate semiconductor materials of the substrate 50, such as silicon. Additionally, the protective layer 212 can be made of a dielectric material, such as silicon oxide.

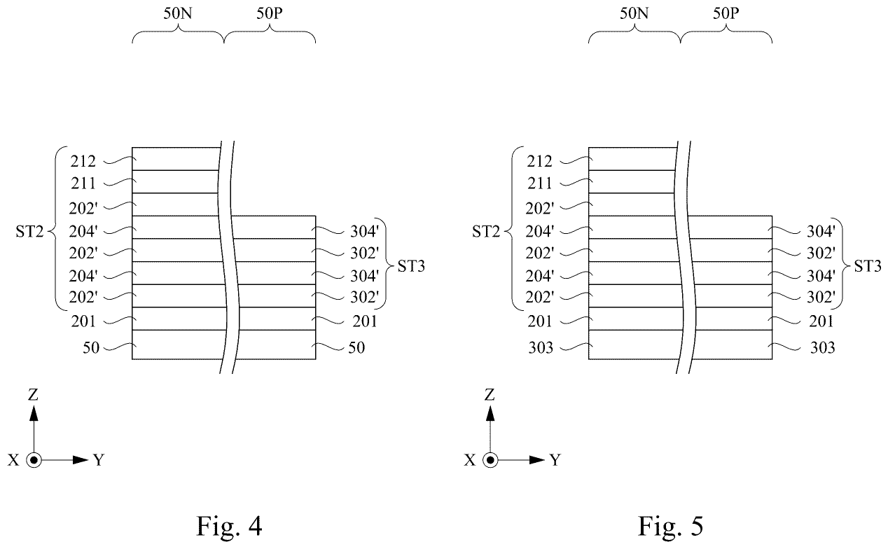

Reference is made to FIG. 4. A protective layer ST3 can be formed by masking the first conductivity type device region 50N. Then, the multi-layer stack ST2 in the second conductivity type device region 50P can be moved. Then, the protective layer ST3 can be epitaxially grown in the second conductivity type device region 50P. The protective layer ST3 can include alternating semiconductor layers 302′ and semiconductor layers 304′. The semiconductor layers 302′ can be formed of a third semiconductor material, and the semiconductor layers 304′ can be formed of a fourth semiconductor material. The semiconductor materials may each be selected from the candidate semiconductor materials of the substrate 50. In the illustrated embodiment, and as subsequently described in greater detail, the semiconductor layers 304′ will be removed and the semiconductor layers 302′ will patterned to form channel regions for the nanostructure-FETs in the second conductivity type device region 50P. The semiconductor material of the semiconductor layers 302′ may be a material suitable for p-type devices, such as germanium tin (Ge₁₋ₓSnₓ, wherein x can be in a range from about 0.01 to 2), a III-V compound semiconductor, a II-VI compound semiconductor, or the like. In some embodiment, the semiconductor layers 302′ can be made of a different material than the semiconductor layers 202′. The semiconductor layers 304′ can be dummy layers that will be removed in subsequent processing to expose top surfaces and bottom surfaces of the semiconductor layers 302′. The semiconductor material of the semiconductor layers 304′ can be a material that has a high etching selectivity from the etching of the semiconductor layers 302′, such as germanium. In some embodiment, the semiconductor layers 304′ may have a same material composition as the semiconductor layers 202′. In some embodiment, the semiconductor layers 204′ and/or the semiconductor layers 304′ may have a same material composition as the buffer layer 201. In some embodiments, the semiconductor layer 302′ can have a thickness in a range from about 1 to 10 nm, such as about 1, 2, 3, 4, 5, 6, 7, 8, 9, or 10 nm.

The protective layer ST3 can be illustrated as including two of the semiconductor layers 304′ and two of the semiconductor layers 302′. It should be appreciated that the protective layer ST3 may include any number of the semiconductor layers 302′ and the semiconductor layers 304′. Each of the layers of the multi-layer stack ST2 may be grown by a process such as vapor phase epitaxy (VPE) or molecular beam epitaxy (MBE), deposited by a process such as chemical vapor deposition (CVD) or atomic layer deposition (ALD), or the like.

Reference is made to FIG. 5. The substrate 50 can be removed from the buffer layer 201. Subsequently, a bonding layer 303 can be formed over the buffer layer 201. In some embodiments, the bonding layer 303 can be in contact with the buffer layer 201. The bonding layer 303 may include dielectric material such as silicon oxide (SiOₓ), silicon dioxide (SiO₂), or other suitable materials. In some embodiments, the bonding layer 303.

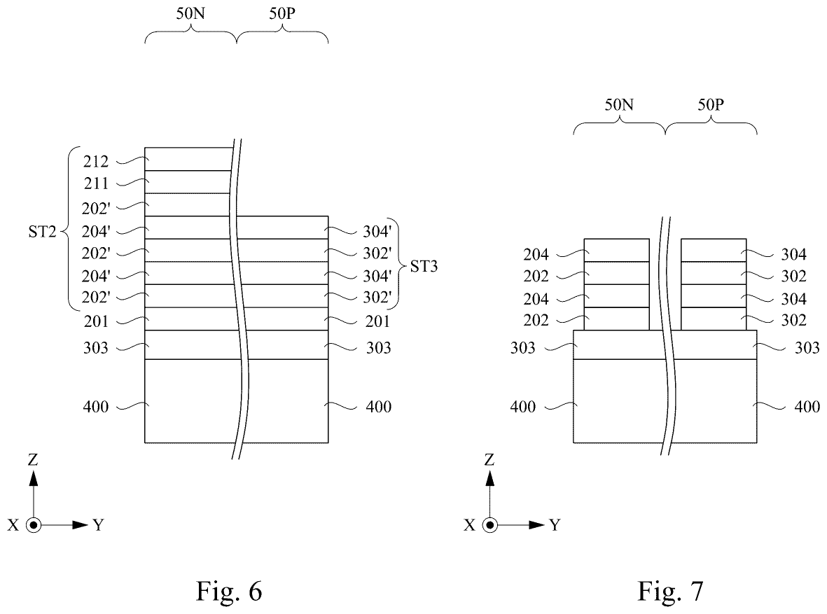

Reference is made to FIG. 6. The multi-layer stacks ST2 and ST3 will be bonded the substrate 400 through the bonding layer 303. In some embodiments, the substrate 400 may have various device elements. Examples of device elements that are formed in the substrate 400 can include transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes.

Reference is made to FIG. 7. The cap layer 211, the protective layer 212, and a topmost one of the semiconductor layers 204′ can be removed. Subsequently, the multi-layer stack ST2 can be patterned to form a fin structure FN2 within the first conductivity type device region 50N and including alternating semiconductor nanostructures 202 and semiconductor nanostructures 204. Additionally, the protective layer ST3 can be patterned to form a fin structure FN3 within the second conductivity type device region 50P and including alternating semiconductor nanostructures 302 and semiconductor nanostructures 304. Specifically, forming the semiconductor nanostructures 202/204 by etching the multi-layer stack ST2 may can define semiconductor nanostructures 202 from the first semiconductor layers 202′ and define semiconductor nanostructures 204 from the second semiconductor layers 204′. Forming the semiconductor nanostructures 302/304 by etching the protective layer ST3 may can define semiconductor nanostructures 302 from the first semiconductor layers 302′ and define nanostructures 304 from the second semiconductor layers 304′. In some embodiments, the semiconductor nanostructures 202/204 and the semiconductor nanostructures 302/304 can be formed by etching trenches in the multi-layer stacks ST2 and ST3. The etching may be any acceptable etch process, such as a reactive ion etch (RIE), neutral beam etch (NBE), the like, or a combination thereof. In some embodiments, the etching may be anisotropic.

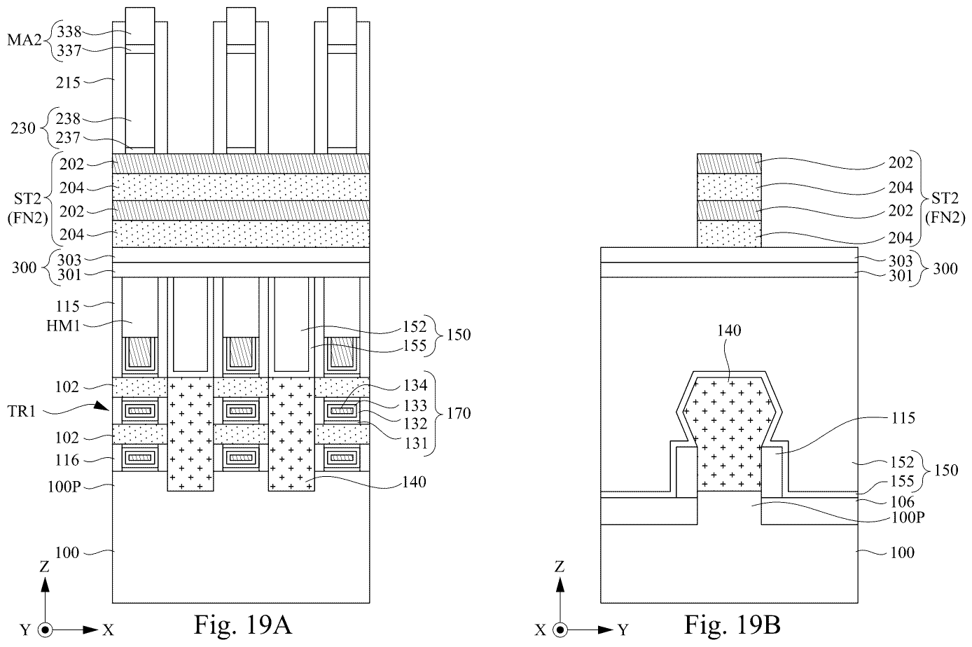

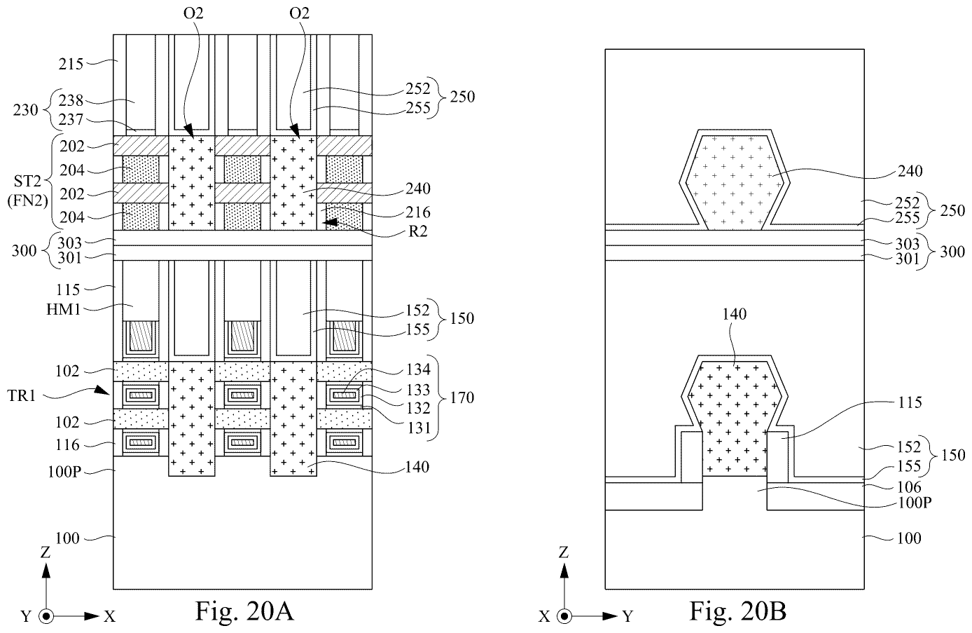

Subsequently, dummy gates and masks (e.g., dummy gate structures 230 shown in FIG. 19A) can be formed formed over the fin structures FN2 and FN3 to cover the nanostructure channel regions. Gate spacers (e.g., spacer 215 shown in FIG. 19A) are subsequently formed by conformally depositing a dielectric material and etching it to leave portions on the sidewalls of the dummy gates and fin structures 65 and 68. Epitaxial source/drain regions (e.g., epitaxial source/drain regions 240 as shown in FIG. 20B) can be formed in source/drain recesses, with materials chosen to create stress in the channel regions for improved device performance. These epitaxial source/drain regions can be grown via epitaxy processes, and both n-type and p-type regions can be formed separately.

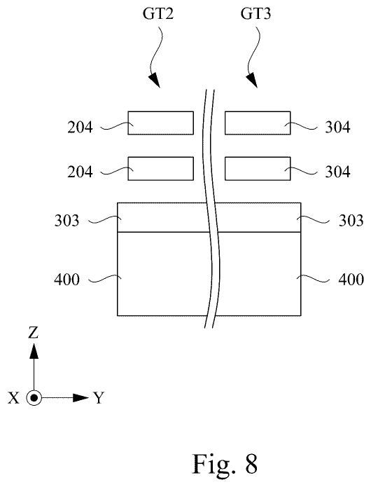

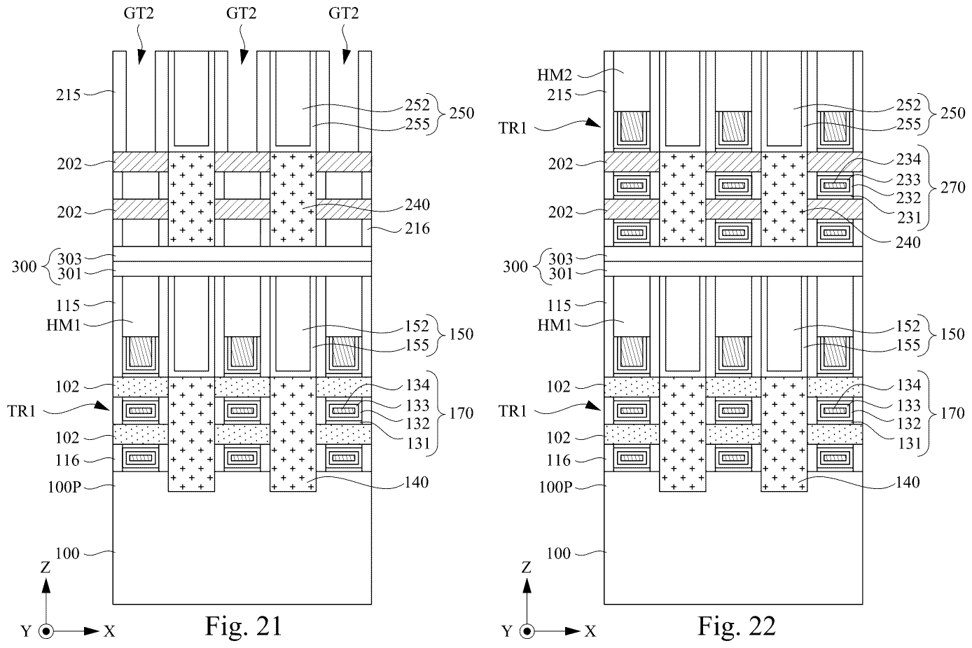

Reference is made to FIG. 8. The dummy gates (e.g., dummy gate structures 230 shown in FIG. 19A) can be removed by etching, forming gate trenches GT2 and GT3 between the gate spacers (e.g., spacers 215 as shown in FIG. 21). This can be done using anisotropic dry etching or selective wet etching, with the semiconductor nanostructures 202/302 serving as etch stops. Next, the semiconductor nanostructures 202/302 can be removed to form the gate trenches GT2/GT3. After removal, each recess G2/GT3 then can expose portions of the nanostructures 204/304, which serve as channel regions in the nanostructure-FETs. These channel regions are located between the epitaxial source/drain regions.

FIGS. 9-12A illustrate the use of semiconductor nanostructures 202 and 302 from FIG. 8 to show how P-dipoles in NFETs and N-dipoles in PFETs can be formed in the first and second conductivity type device regions 50N and 50P, respectively.

Reference is made to FIG. 9. Oxide layers 231 and 331 can be formed on the semiconductor nanostructures 202 and 204 to support the overall device performance, on the integration of germanium-based materials. The formation of the oxide layers 231 and 331 can serve as stabilization of the electrical properties of the nanostructures. The oxide layers 231 and 331 can be formed using an annealing process, including heating the semiconductor nanostructures 202 and 302 in an oxygen-containing environment. The formation of the oxide layers 231 and 331 can depend on the composition of the underlying semiconductor nanostructures 202 and 302. In some embodiments, the semiconductor nanostructures 202, which are located in the first conductivity type device region (50N), can be made of GeSi. After annealing, the oxide layer 231 formed on the semiconductor nanostructures 202 can be GeSiO₂. The oxide layer 231 can include both germanium and silicon oxides, resulting in a mixed oxide composition. In some embodiments, in the second conductivity type device region (50P), the semiconductor nanostructures 302 can be made of GeSn. After annealing, the oxide layer 331 formed on the nanostructures 304 can be GeSnO₂. The oxide layer 331 can include both germanium and tin oxides, resulting in a mixed oxide composition.

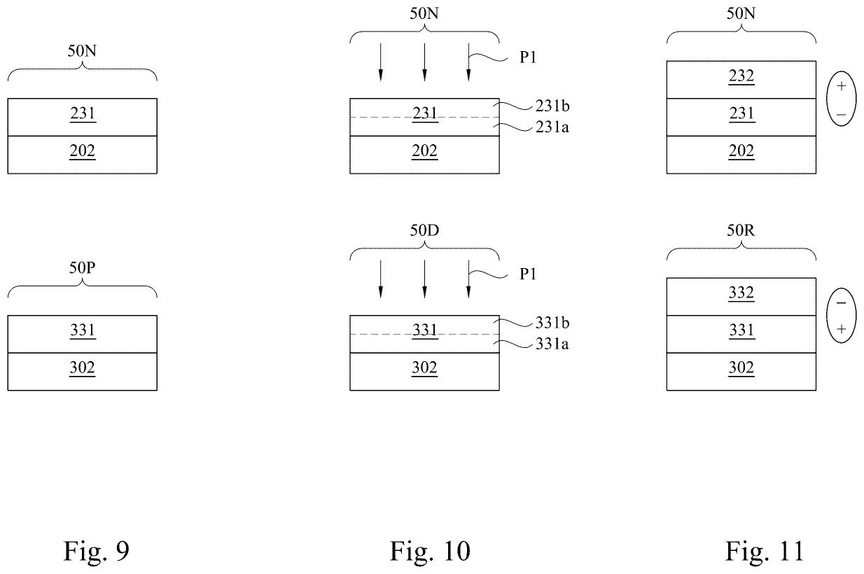

Reference is made to FIG. 10. The germanium (Ge) element present in the oxide layers 231 and 331 can be then removed to improve the material characteristics for subsequent device processing. This removal process P1 can be carried out using wet etching, which takes advantage of the solubility of GeO₂ in etching solutions. The targeted removal of GeO₂ from the oxide layers 231 and 331 can help to achieve a more refined and tailored oxide composition. Specifically, in this wet etching process, a chemical solution that selectively dissolves GeO₂ can be used to remove germanium from the oxide layers. The etching solution can be chosen for its ability to react with and dissolve GeO₂ while minimizing effects on other components, such as silicon or tin oxides. This selective etching can lead to an increase in the oxygen concentration within the oxide layers 231 and 331. By removing germanium from the oxide layer 231 and 331, the remaining oxides, such as SiO₂ or SnO₂, can achieve a higher oxygen density, optimizing the electrical properties of the semiconductor device.

The removal of germanium can result in an increased difference in oxygen concentration between the oxide layers 231 and 331 and the subsequently formed dipole layers (e.g., dipole layers 232 and 332 shown in FIG. 11). This difference can enhance the distinction between P-dipoles and N-dipoles, which are formed during the next stages of device fabrication. Specifically, P-dipoles can be formed in n-type FETs (NFETs), and N-dipoles can be formed in p-type FETs (PFETs), where the oxygen concentration in the underlying oxide layer can affect the dipole characteristics. By increasing the oxygen concentration in the oxide layers 231 and 331, a more oxygen gradient can be created between the oxide layers 231 and 331 and the dipole layers 232 and 332, establishing an improved distinction between P-dipoles and N-dipoles, thereby contributing to effective threshold voltage (Vₜ) control and enhanced device performance.

If the oxide layer 231 initially includes GeSiO₂, after the wet etching process, the removal of Ge can lead to the transformation of the oxide layer 231 into SiO₂. This transformation can increase the stability and oxygen content of the oxide layer 231. Similarly, if the oxide layer 331 initially includes GeSnO₂, after the wet etching process, the removal of Ge can lead to the transformation of the oxide layer 231 into SnO₂. This transformation can also increase the stability and oxygen content of the oxide layer 331.

In some embodiments, the removal process P1 can result in variations in the oxygen atomic concentration within the oxide layer 231. This occurs because the wet removal process P1 may selectively remove germanium from the oxide layer 231, causing a shift in the remaining composition. For example, the upper portion 231b of the oxide layer 231 may have a higher oxygen atomic concentration than the lower portion 231a. This happens as the removal of germanium during the removal process P1 leads to an increase in the relative amount of oxygen present in the oxide layer 231. Consequently, in some embodiments, the oxygen atomic concentration within the oxide layer may 231 forms a gradient.

In some embodiments, germanium may still be present in oxide layer 231, but the germanium atomic concentration in the upper portion 231b may be lower compared to the lower portion 231a. This is because the etching process may be more effective at removing germanium from the upper portion, leaving a higher concentration in the lower portion. In such cases, the germanium concentration in the oxide layer 231 may also form a gradient. Additionally, in some embodiments, the silicon atomic concentration in the upper portion 231b of the oxide layer 231 may be higher than in the lower portion 231a. This can occur because, as germanium is selectively removed, the silicon content becomes more concentrated in the upper portion 231b.

Similarly, for the oxide layer 331, the removal process P1 can also lead to variations in the oxygen atomic concentration. For example, the upper portion 331b of the oxide layer 331 may have a higher oxygen atomic concentration than the lower portion 331a, due to the selective removal of germanium, which increases the relative oxygen concentration in the upper portion region. In some embodiments, the oxygen concentration within oxide layer 331 can be a gradient.

Furthermore, germanium may still be present in oxide layer 331, but its atomic concentration in the upper portion 331b may be lower than that in the lower portion 331a, owing to the differential effectiveness of the removal process P1, creating a gradient in germanium concentration, which contributes to tailored device behavior. In some embodiments, the tin atomic concentration in the upper portion 331b of oxide layer 331 may be higher than in the lower portion 331a. This occurs because, as germanium is removed from the oxide layer, the remaining tin concentration increases. In some embodiments, the tin concentration within the oxide layer 331 can be a gradient.

Reference is made to FIG. 11. The formation of dipoles in this disclosure can achieve precise control over the threshold voltage (Vₜ) of both NMOS and PMOS transistors in, such as the sequential CFET application. The dipoles can be formed through the intentional difference in oxygen concentration between the oxide layers 231 and 331 and the dipole layers 232 and 332, creating a localized electric field at the oxide/dipole interface, which can help to modulate the potential barrier in the underlying channel. By creating distinct P-dipoles for NFETs and N-dipoles for PFETs, this disclosure can ensure that each transistor type can achieve its operating characteristics, in terms of switching speed, power consumption, and threshold voltage stability. In some embodiments, the formation of dipoles can apply on channel materials, such as GeSi and GeSn for their improved carrier mobility.

Specifically, the dipole layer 232 can be formed on the oxide layer 231, and the dipole layer 332 can be formed on the oxide layer 331. The formation of the dipole layers 232 and 332 can be based on creating an intentional oxygen concentration gradient between the oxide and dipole layers. The difference in oxygen concentration between dipole layer 232 and oxide layer 231 results in the formation of a P-dipole, which is utilized for the n-type FET (NFET) region. Similarly, the difference between dipole layer 332 and oxide layer 331 creates an N-dipole for the p-type FET (PFET) region.

In some embodiments, the dipole layer 332 can be made from the same material a the dipole layer 232, allowing for the simultaneous formation of dipole layers 232 and 332 for both NFETs and PFETs, which can simplify the manufacturing process and reduce the complexity associated with depositing different materials for each transistor type. The use of a common dipole material can provide a approach to maintaining process uniformity and reducing manufacturing variability. In some embodiments, the dipole layer 332 can be made from a different material than the dipole layer 232.

In some embodiments, the dipole layers 232 and 332 can be made of metal oxides that are chosen based on their oxygen areal density. The oxygen areal density difference between the oxide layers 231 and 331 and the dipole layers 232 and 332 can form P-dipoles and N-dipoles. The dipole layer material may have an oxygen areal density that is intermediate between that of the underlying oxide layer (e.g., oxide layer 231 or oxide layer 331) and have the desired areal density for effective dipole formation. For instance, if the oxide layer 231 is made of SiO₂ and the oxide layer 331 is made of SnO₂, the dipole layers 232 and 332 can be made of materials such as In₂O₃, CeO₂, Sc₂O₃, MgO, or combinations thereof. These materials can be selected to achieve an oxygen areal density that can fall between that of SiO₂ and SnO₂. Specifically, the ratio of oxygen areal density (i.e., σ) of these materials to that of SiO₂ (i.e., σ_{SiO2}) can be between 1 and the ratio for SnO₂ (approximately 1.17). For example, the ratios for In₂O₃, CeO₂, Sc₂O₃, and MgO compared to SiO₂ can be approximately 1.14, 1.1, 1.1, and 1.14, respectively. These ratios can ensure that the resulting dipole layers 232 and 332 can create the electric dipole effect at the oxide/dipole interface. In some embodiments, a peak of metal oxide profile can located between the oxide layer 231/331 and the gate dielectric layer 233/333. In some embodiments, dipole atom profile in the dipole layers 232 and 332 can be detected by an energy dispersive spectroscopy (EDS), an electron energy loss spectroscopy (EELS), a secondary ion mass spectroscopy (SIMS), or combinations thereof.

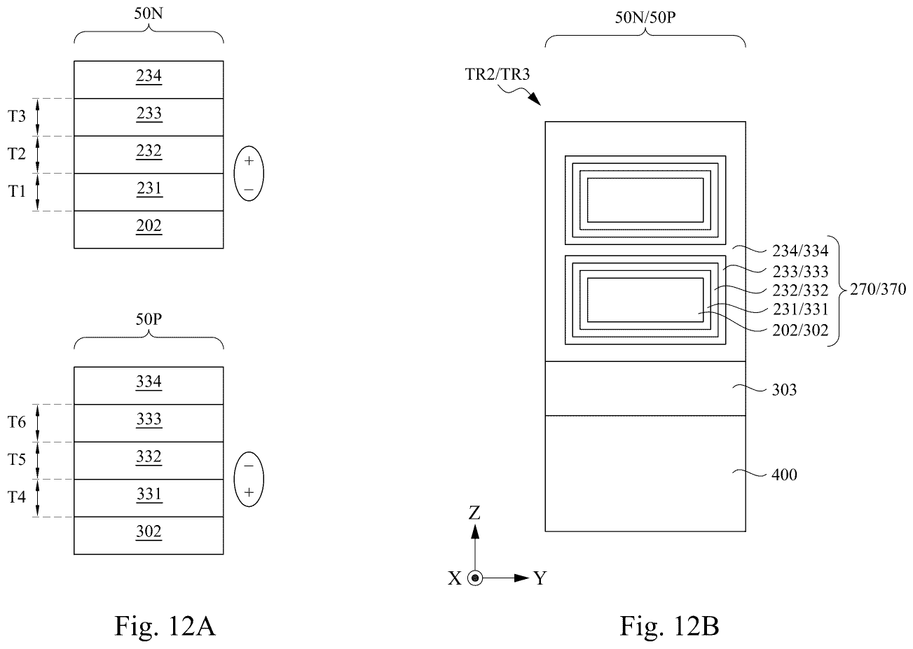

Reference is made to FIGS. 12A and 12B. Gate dielectric layers 233 and 333 can be formed over the dipole layers 232 and 332, respectively. In some embodiments, the gate dielectric layers 233 and 333 may be formed using a same deposition process. After the gate dielectric layers 233 and 333 are formed, the gate electrode layers 234 and 334 are formed in the gate trenches 74 and 78 and over the gate dielectric layers 233 and 333. Accordingly, metal gate structures 270 and 370 can be formed.

Specifically, the metal gate structures 270 and 370 can be formed in the gate trenches GT2 and GT3, such that the metal gate structures 270 and 370 may wrap around the semiconductor nanostructures 202 and 302, respectively. In some embodiments, the metal gate structure 270 may include the oxide layer 231, the dipole layer 232 over the oxide layer 231, the gate dielectric layer 233 over the dipole layer 232, and the gate electrode layer 234 over the gate dielectric layer 233. In some embodiments, the metal gate structure 370 may include the oxide layer 331, the dipole layer 332 over the oxide layer 331, the gate dielectric layer 333 over the dipole layer 332, and the gate electrode layer 334 over the gate dielectric layer 333.

As shown in FIG. 12A, the oxide layer 231 can have a thickness T1, the dipole layer 232 can have a thickness T2, and the gate dielectric layer 233 can have a thickness T3. In some embodiments, the thickness T3 of the gate dielectric layer 233 can be greater than the thickness T1 of the oxide layer 231 and/or thickness T2 of the dipole layer 232. By way of example but not limiting the present disclosure, the thickness T1 can be in a range from about 0.1 to 1 nm, such as about 0.1, 0.2, 0.3, 0.4, 0.5, 0.6, 0.7, 0.8, 0.9 or 1 nm. The thickness T2 can be in a range from about 0.1 to 1 nm, such as about 0.1, 0.2, 0.3, 0.4, 0.5, 0.6, 0.7, 0.8, 0.9 or 1 nm. The thickness T3 can be in a range from about 1 to 5 nm, such as about 1, 2, 3, 4, or 5 nm. In some embodiments, the thickness T2 of the dipole layer 232 can be greater than, less than, or substantially equal to the thickness T1 of the oxide layer 231.

Similarly, the oxide layer 331 can have a thickness T4, the dipole layer 332 can have a thickness T5, and the gate dielectric layer 333 can have a thickness T6. In some embodiments, the thickness T6 of the gate dielectric layer 333 can be greater than the thickness T4 of the oxide layer 331 and/or thickness T5 of the dipole layer 332. By way of example but not limiting the present disclosure, the thickness T4 can be in a range from about 0.1 to 1 nm, such as about 0.1, 0.2, 0.3, 0.4, 0.5, 0.6, 0.7, 0.8, 0.9 or 1 nm. The thickness T5 can be in a range from about 0.1 to 1 nm, such as about 0.1, 0.2, 0.3, 0.4, 0.5, 0.6, 0.7, 0.8, 0.9 or 1 nm. The thickness T6 can be in a range from about 1 to 5 nm, such as about 1, 2, 3, 4, or 5 nm. In some embodiments, the thickness T5 of the dipole layer 332 can be greater than, less than, or substantially equal to the thickness T4 of the oxide layer 331.

In some embodiments, the gate dielectric layer 233/333 may include high-k dielectric. In some embodiments, the gate dielectric layer 233 and/or 333 can be Hf- and Zr-based oxide. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the gate dielectric layer 233 can be made of a same material as the gate dielectric layer 333. In some embodiments, the gate dielectric layer 233 can be made of a different material than the gate dielectric layer 333. The gate electrode layers 234 and 334 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

The metal gate structure 270, the first source/drain epitaxy structures (e.g., epitaxial source/drain regions 240 as shown in FIG. 20B) on opposite sides of the metal gate structure 270, and the semiconductor nanostructures 202 that are in contact with the first source/drain epitaxy structures may collectively serve as a transistor TR2 as described in FIG. 1A. In such condition, the semiconductor nanostructures 202 may also be referred to as channel layers of the transistor TR2. Similarly, the metal gate structure 370, the second epitaxial source/drain regions 240 (e.g., epitaxial source/drain regions 240 as shown in FIG. 20B) on opposite sides of the second metal gate structure 370, and the semiconductor nanostructures 302 that are in contact with the second source/drain epitaxy structures may collectively serve as a transistor TR3. In such condition, the semiconductor nanostructures 302 may also be referred to as channel layers of the transistor TR3.

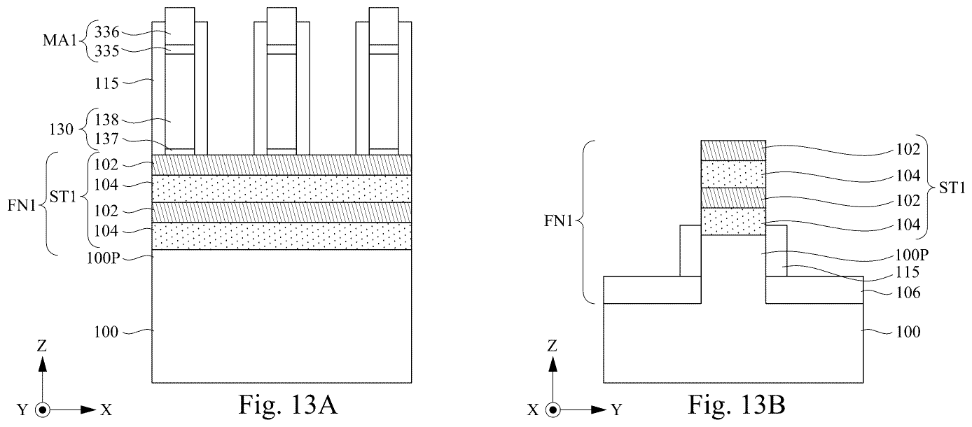

Reference is made to FIGS. 13A-22. FIGS. 13A-22 illustrate schematic cross-sectional views of intermediate stages in the formation of a semiconductor structure in accordance with some embodiments. FIGS. 13A, 14A, 15, 16, 17A, 17B, 18A, 19A, 20A, 21, and 22 illustrate cross-sectional views obtained from reference cross-sections A-A′ in FIG. 1A, and FIGS. 13B, 14B, 18B, 19B, and 20B illustrate cross-sectional views obtained from reference cross-sections B-B′ in FIG. 1A. It is understood that additional operations can be provided before, during, and after the processes shown by FIGS. 13A-22, and some of the operations described below can be replaced or eliminated, for additional embodiments of the method. The order of the operations/processes may be interchangeable. In addition, the present disclosure may repeat reference numerals and/or letters in the various examples. This repetition is for the purpose of simplicity and clarity and does not in itself dictate a relationship between the various embodiments and/or configurations discussed.

Reference is made to FIGS. 13A and 13B. A multi-layer stack ST1 including alternating semiconductor nanostructures 102 and semiconductor nanostructures 104 can be formed over a substrate 100. A patterning process can be performed to the multi-layer stack ST1 and the substrate 100 to form a fin structure FN1. In some embodiments, the fin structure FN1 may include a semiconductor strip 100P protruding over the substrate 100. In some embodiments, the substrate 100 can be substantially similar to the substrate 50 illustrated in FIG. 2 in terms of their material and manufacturing methods. In some embodiments, the semiconductor nanostructures 102 can be substantially similar to the semiconductor nanostructures 202/302 illustrated in FIGS. 2-7 in terms of their material and manufacturing methods. In some embodiments, the semiconductor nanostructures 104 can be substantially similar to the semiconductor nanostructures 204/304 illustrated in FIGS. 2-7 in terms of their material and manufacturing methods.

After the fin structure FN1 is formed, an isolation structure 106 (see FIG. 13B) can be formed over the substrate 100 and laterally surrounding the fin structure FN1. The isolation structures 106 may be shallow trench isolation (STI) structures, suitable isolation structures, combinations of the foregoing, or the like. In some embodiments, the isolation structures 106 may be made of a dielectric material, such as oxide (e.g., silicon oxide), nitride (e.g., silicon nitride), or combinations thereof.

Dummy gate structures 130 can be formed over the substrate 100 and crossing the fin structure FN1. In some embodiments, each of the dummy gate structures 130 can include a dummy gate dielectric 137 and a dummy gate electrode 138 over the dummy gate dielectric 137. The dummy gate dielectric 137 may be, for example, silicon oxide, silicon nitride, a combination thereof, or the like, and may be deposited or thermally grown according to acceptable techniques. The dummy gate electrode 138 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 138 and the dummy gate dielectric 137 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 138 may be deposited by physical vapor deposition (PVD), chemical vapor deposition (CVD), sputter deposition, or other techniques for depositing the selected material. In some embodiments, the dummy gate dielectric 137 may be formed by thermal oxidation.

In some embodiments, each of the patterned masks MA1 can include a first hard mask 335 and a second hard mask 336 over the first hard mask 335. The first hard mask 335 and the second hard mask 336 may be made of different materials. In some embodiments, the first hard mask 335 may be formed of silicon nitride, and the second hard mask 336 may be formed of silicon oxide.

Spacers 115 can be formed on opposite sidewalls of each of the dummy gate structures 130 (see FIG. 13A), and on opposite sidewalls of the fin structure FN (see FIG. 13B). In some embodiments, portions of the spacers 115 on opposite sidewalls of each of the dummy gate structures 130 can be referred to as gate spacers, and portions of the spacers 115 on opposite sidewalls of the fin structure FN can be referred to as fin spacers. In some embodiments, the fin spacers are landed on the isolation structures 106, and may be kept or removed in later processes, depending on embodiments. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130 and on sidewalls of the fin structure FN. In some embodiments, the remaining vertical portions of the spacer layer can be referred to as the spacers 115. The spacer layer may be deposited using techniques such CVD, ALD, or the like.

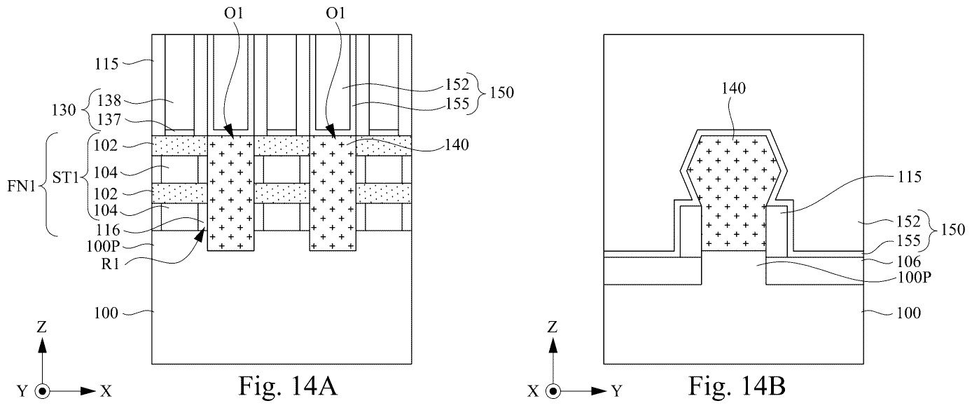

Reference is made to FIGS. 14A and 14B. An etching process is performed to remove portions of the fin structure FN1 (or the multi-layer stack ST1) by using the dummy gate structures 130 and the spacers 115 as etch mask, so as to form source/drain recesses O1. In some embodiments, the etching process may be wet etch, dry etch, or combinations thereof. In some embodiments, the bottommost ends of the source/drain openings O1 may be lower than the bottommost semiconductor layer 104.

Then, the semiconductor nanostructures 104 can be laterally etched to form sidewall recesses R1 through the source/drain recesses O1. In some embodiments, the sidewalls of the semiconductor layers 104 and 204 may be etched using isotropic etching processes, such as wet etching or the like. Subsequently, inner spacers 116 can be formed in the sidewall recesses R1 on opposite ends of each of the semiconductor nanostructures 104. In some embodiments, the inner spacers 116 may be formed by, for example, depositing a dielectric layer blanket over the substrate 100 and filling the sidewall recesses R1, and then performing an anisotropic etching to remove portions of the dielectric layer outside the sidewall recesses R1, leaving the remaining portions of the dielectric layer in the sidewall recesses R1 as the inner spacers 116. The inner spacers 116 may be deposited by a conformal deposition process, such as CVD, ALD, or the like. The dielectric layer may include a material such as SiN, SiOCN, SiCN, SIOC, although any suitable material, such as low-dielectric constant (low-k) materials having a k-value less than about 3.5, may be utilized.

Afterwards, epitaxial source/drain regions 140 can be formed in of the source/drain openings O1. The source/drain epitaxy structures 140 may be formed by suitable deposition process, such as a selective epitaxial growth (SEG) process. In some embodiments, the SEG process may selectively grow a semiconductor material on exposed semiconductor surfaces, such as the exposed surfaces of the semiconductor strip 100P and the exposed surfaces of the semiconductor nanostructures 102. In some embodiments, an implantation process may be performed to the epitaxial source/drain regions 140. In some embodiments, the epitaxial source/drain regions 140 may be doped with n-type dopants, such as phosphorus (P), arsenic (As), or antimony (Sb), or the like. In some embodiments, the epitaxial source/drain regions 140 may be doped with p-type dopants, such as boron (B), gallium (Ga), indium (In), aluminium (Al), or the like. In some embodiments, each of the epitaxial source/drain regions 140 may include different layers (e.g., L1, L2 . . . etc), in which the layers may include different dopant concentrations.

Subsequently, a contact etch stop layer (CESL) 155 can be formed covering the epitaxial source/drain regions 140. Afterwards, an interlayer dielectric (ILD) layer 152 can be formed over the CESL 155. Then, a planarization process, such as CMP, is performed to the ILD layer 152 and the CESL 155 until the dummy gate structures 130 are exposed. In some embodiments, the CESL 155 and the ILD layer 152 can be collectively referred to as an isolation structure 150.

In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques.

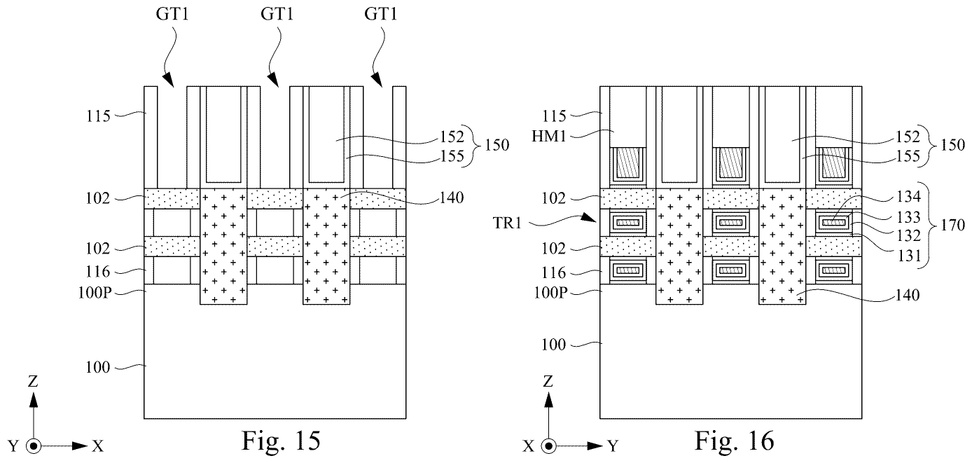

Reference is made to FIG. 15. The dummy gate structures 130 can be removed to form gate trenches GT1 between each pair of the spacers 115. Then, an etching process is performed to remove the semiconductor nanostructures 104 through the gate trenches GT1, such that that the semiconductor layers 102 can be suspended over the substrate 100.

Reference is made to FIG. 16. FIG. 16 shows how P-dipoles/N-dipoles can be formed using the semiconductor nanostructures 102. Oxide layers 131 can be formed on the nanostructures 102, using an annealing process. In some embodiments, if the semiconductor nanostructures 102 are within the first conductivity region, the semiconductor nanostructures 102, such as including GeSi, can form oxide layers, such as including GeSiO₂. In some embodiments, if the semiconductor nanostructures 102 are within the second conductivity region having a conductivity type opposite to the first conductivity region, the semiconductor nanostructures 102, such as including GeSn, can form oxide layers, such as including GeSnO₂. Wet etching can be used to selectively remove germanium, transforming GeSiO₂ to SiO₂ and GeSnO₂ to SnO₂. This process can increases oxygen concentration, optimizing the electrical properties and creating a gradient for dipole formation. The difference in oxygen concentration between oxide layers 131 and dipole layers 132 can enhance the distinction between P-dipoles (NFETs) and N-dipoles (PFETs), allowing for effective threshold voltage control and improved transistor performance. The dipole layers 132 can be formed from materials like In₂O₃, CeO₂, Sc₂O₃, and MgO, which can provide an oxygen density between that of SiO₂ and SnO₂, ensuring a suitable electric dipole effect.

Subsequently, gate dielectric layers 133 can be formed over the dipole layers 132, followed by gate electrode layers 134. A planarization process, such as CMP, can be performed to remove the excess dipole layer 132, the excess gate dielectric layer 133, and the excess gate electrode layer 134 until the isolation structures 150 are exposed. Therefore, the gate structures 170 can be formed to include the oxide layer 131, the dipole layer 132, the gate dielectric layer 133, and the gate electrode layer 134. The gate structures 170 can wrap around the semiconductor nanostructures 102. The combination of these layers forms effective metal gate structures for stacked NMOS/PMOS transistors TR1, contributing to enhanced device density and electrical performance. In some embodiments, the oxide layer 131, the dipole layer 132, the gate dielectric layer 133, and the gate electrode layer 134 can be substantially similar to the oxide layer 231/331, the dipole layer 232/332, the gate dielectric layer 233/333, and the gate electrode layer 234/334 illustrated in FIGS. 9-11 in terms of their material and manufacturing methods.

The first metal gate structures 170 can be then etched back, such that top surfaces of the metal gate structures 170 can lower than top surfaces of the spacers 115. Afterwards, hard masks HM1 can be formed over the respectively metal gate structures 170. The hard masks HM1 may be formed by, for example, depositing a dielectric layer over the etched back first metal gate structures 170, and then performing a planarization process, such as CMP, on the dielectric layer until the isolation structure 150 is exposed.

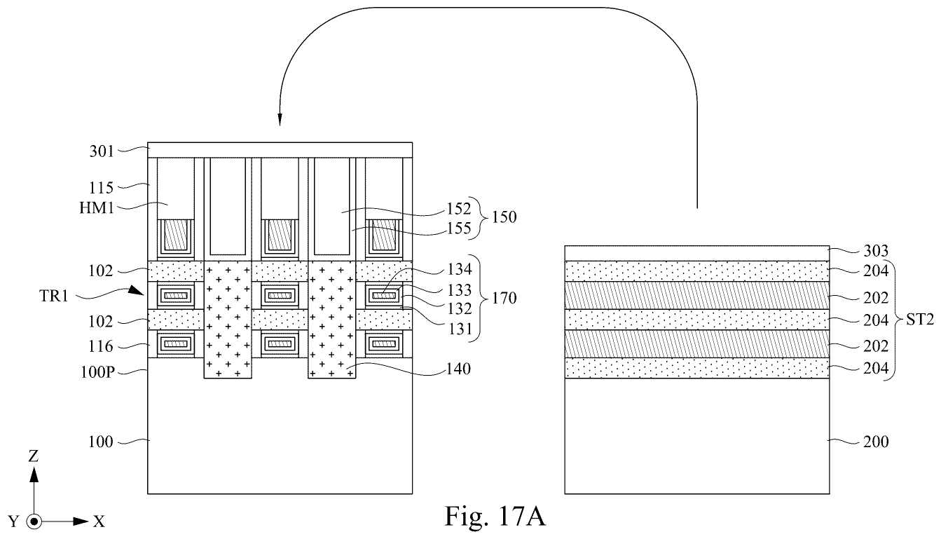

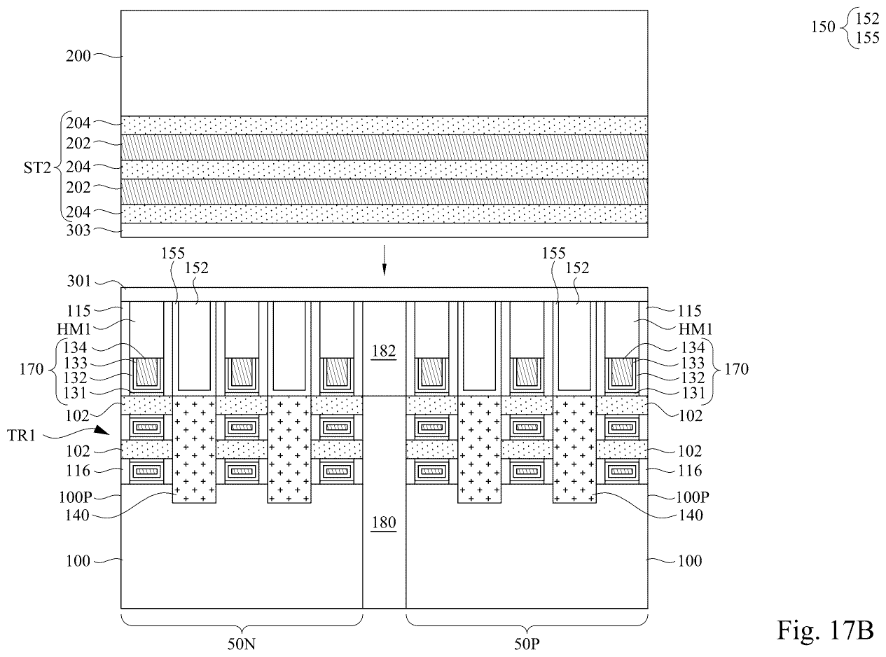

Reference is made to FIGS. 17A and 17B. A bonding layer 301 can be formed over the structure shown in FIG. 16. In greater detail, the bonding layer 301 may be in contact with the hard masks HM1, the spacers 115, and the isolation structures 150. The bonding layer 301 may include dielectric material such as silicon oxide (SiOₓ), silicon dioxide (SiO₂), or other suitable materials. In some embodiments, the bonding layer 301 may be deposited over the structure shown in FIG. 16 using suitable deposition process, such as CVD, PVD, ALD, or the like.

On the other hand, a substrate 200 is provided. The multi-layer stack ST2 including alternating semiconductor layers 202′ and semiconductor layers 204′ are formed over the substrate 200. A bonding layer 303 can be formed over the multi-layer stack ST2. In some embodiments, the bonding layer 303 can be in contact with the topmost semiconductor layer 204. In some embodiments, the bonding layers 301 and 303 may include a same bonding material. In other embodiments, the bonding layers 301 and 303 may include different bonding materials. In some embodiments, the substrate 200 can be substantially similar to the substrate 200 illustrated in FIGS. 13A and 13B in terms of their material and manufacturing methods. In some embodiments, the materials and the formation methods of the multi-layer stack ST2 including alternating semiconductor layers 202′ and 204′, and the bonding layer 303 have been described above, and relevant details will not be repeated.

The substrate 100 will be bonded to the substrate 200 as indicated by the arrow shown in FIGS. 17A and 17B through the bonding layers 301 and 303. The bonding layers 301 and 303 can be bonded with each other using a suitable technique. In some embodiments, the bonding process may further include applying surface treatments to the surfaces of the bonding layers 301 and 303, respectively. The surface treatment may include a plasma treatment. The plasma treatment may be performed in a vacuum environment. After the plasma treatment, the surface treatment may further include a cleaning process (e.g., a rinse with deionized water, or the like) that may be applied to the bonding layers 301 and 303. The bonding layers 301 and 303 are pressed against each other to initiate a pre-bonding of the substrates 100 and 200. The pre-bonding may be performed at room temperature (between about 21 degrees and about 25 degrees). After the pre-bonding, an annealing process may be applied to the bonding layers 301 and 303 that have already been pressed against each other. The annealing process results in an increased bonding force between the bonding layers 301 and 303, such that even if the bonding layers 301 and 303 are no longer subjected to the pressing force, they will not delaminate or peel from each other. In some embodiments, the bonding layers 301 and 303 can be collectively referred to as a bonding structure 300. In some embodiments, the bonding layers 301 and 303 each can be referred to as dielectric layer or isolation layer, and the bonding structure 300 can be referred to as dielectric structure or an isolation structure. In some embodiments, the bonding layer 301/303 can have a thickness in a range from about 10 nm to 100 μm, such as about 0.001, 0.005, 0.01, 0.05, 0.1, 0.5, 1, 5, 10, 50, or 100 μm.

As shown in FIG. 17B, the difference between FIGS. 17A and 17B is that FIG. 17B further illustrates the presence of different devices, such as PMOS and NMOS, within the same layer of the semiconductor structure. Specifically, the substrate 100 includes a first conductivity type device region (50N) and a second conductivity type device region (50P), enabling the co-existence of both types of devices. The subsequent manufacturing process and the structure for the opposite side of the substrate 300 can refer to FIGS. 2-12B for further details. In some embodiments, a first dielectric layer 180 can be formed to interpose between different devices, such as PMOS and NMOS. In some embodiments, a second dielectric layer 182 can be formed over the first dielectric layer 180 and may be made of a different material than the dielectric layer 180. In some embodiments, the first dielectric layer 180 and/or the second dielectric layer 182 may including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes(BCB), or polyimide.

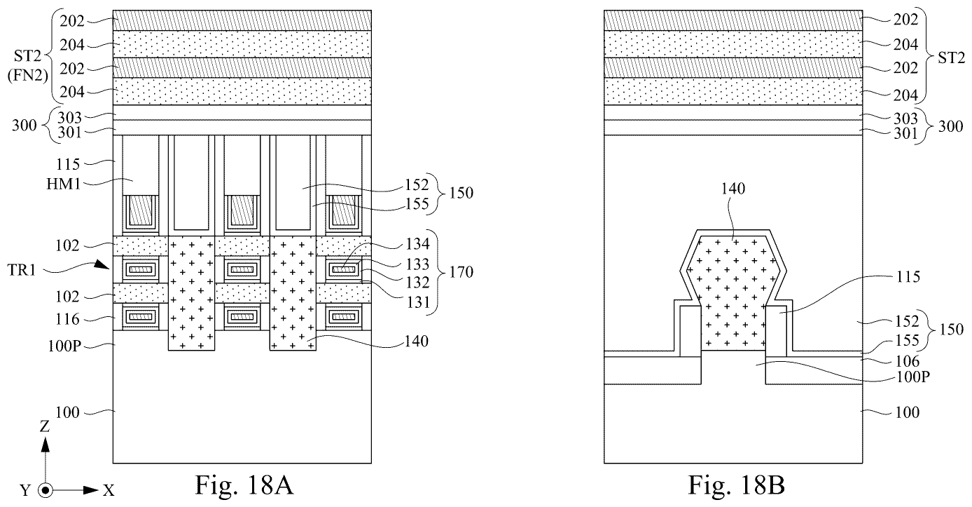

Reference is made to FIGS. 18A and 18B. A grinding process can performed on the backside of the substrate 200, so as to remove the substrate 200 until the topmost semiconductor layer 202 is exposed.

Reference is made to FIGS. 19A and 19B. A patterning process is performed to the second stack ST2 to form a fin structure FN2. In some embodiments, the patterning process may include forming a patterned photoresist layer over the second stack ST2, and then performing an etching process to remove unwanted portions of the second stack ST2 exposed by the patterned photoresist layer. The fin structure FN2 may include a remaining portion of the second stack ST2. Specifically, forming the semiconductor nanostructures 202/204 by etching the multi-layer stack ST2 may can define semiconductor nanostructures 202 from the first semiconductor layers 202′ and define semiconductor nanostructures 204 from the second semiconductor layers 204′.

Dummy gate structures 230 can formed crossing the fin structure FN2. In some embodiments, each of the dummy gate structures 230 includes a dummy gate dielectric 237 and a dummy gate electrode 238 over the dummy gate dielectric 237. The materials of the dummy gate dielectric 237 and the dummy gate electrode 234 may be similar to the materials of the dummy gate dielectric 137 and the dummy gate electrode 138, and thus relevant details will not be repeated.

The dummy gate electrode 234 and the dummy gate dielectric 237 may be formed by, for example, depositing a dummy dielectric layer and a dummy gate layer over the fin structure FN2, forming patterned masks MA2 over the dummy gate layer, and then performing an etching process to the dummy dielectric layer and the dummy gate layer by using the patterned masks MA2 as etch mask. In some embodiments, each of the patterned masks MA2 includes a first hard mask 337 and a second hard mask 338 over the first hard mask 337. In some embodiments, the first hard mask 337 may be formed of silicon nitride, and the second hard mask 338 may be formed of silicon oxide.

Spacers 215 can be formed on opposite sidewalls of each of the dummy gate structures 230. The material and the formation method of the spacers 215 may be similar to those described with respect to the spacers 115, and thus relevant details will not be repeated.

Reference is made to FIGS. 20A and 20B. An etching process is performed to remove portions of the fin structure FN2 (or second stack ST2) by using the dummy gate structures 230 and the spacers 215 as etch mask, so as to form source/drain openings O2. Then, the semiconductor layers 204 are laterally etched to form sidewall recesses R2, and inner spacers 216 are formed in the sidewall recesses opposite ends of each of the semiconductor layers 204. The material and the formation method of the inner spacers 216 may be similar to those described with respect to the inner spacers 116, and thus relevant details will not be repeated.

Epitaxial source/drain regions 240 can be formed on opposite ends of each of the semiconductor layers 202. In some embodiments, an implantation process may be performed to the epitaxial source/drain regions 240. In some embodiments, the epitaxial source/drain regions 240 may be doped with n-type dopants, such as phosphorus (P), arsenic (As), or antimony (Sb), or the like. In some embodiments, the epitaxial source/drain regions 140 may be doped with p-type dopants, such as boron (B), gallium (Ga), indium (In), aluminium (Al), or the like. In some embodiments, each of the epitaxial source/drain regions 240 may include different layers (e.g., L1, L2 . . . etc), in which the layers may include different dopant concentrations. In some embodiments, the first epitaxial source/drain regions 140 and the second epitaxial source/drain regions 240 may include dopants with opposite conductivity types. For example, if the first epitaxial source/drain regions 140 are doped with n-type dopants, the second epitaxial source/drain regions 240 are doped with p-type dopants. Similarly, if the first epitaxial source/drain regions 140 are doped with p-type dopants, the second epitaxial source/drain regions 240 are doped with n-type dopants. In some embodiments, the first epitaxial source/drain regions 140 and the second epitaxial source/drain regions 240 may include dopants with the same conductivity type.

A contact etch stop layer (CESL) 255 can be formed covering the second epitaxial source/drain regions 240. Afterwards, an interlayer dielectric (ILD) layer 252 can be formed over the CESL 255. Then, a planarization process, such as CMP, is performed to remove excess materials of the CESL 255 and the ILD layer 252 until the dummy gate structures 230 are exposed. In some embodiments, the patterned masks MA2 can be removed during the planarization process. In some embodiments, the CESL 255 and the ILD layer 252 can be collectively referred to as an isolation structure 250.

Reference is made to FIG. 21. The dummy gate structures 230 can be removed to form gate trenches GT2 between each pair of the spacers 215. Then, an etching process can be performed to remove the semiconductor nanostructures 204 through the gate trenches GT2, such that that the semiconductor nanostructures 202 can be suspended over the bonding structure 300.

Reference is made to FIG. 22. FIG. 22 shows how P-dipoles/N-dipoles can be formed using the semiconductor nanostructures 202. Oxide layers 231 can be formed on the nanostructures 202, using an annealing process. In some embodiments, if the semiconductor nanostructures 202 are within the first conductivity region, the semiconductor nanostructures 202, such as including GeSi, can form oxide layers, such as including GeSiO₂. In some embodiments, if the semiconductor nanostructures 202 are within the second conductivity region having a conductivity type opposite to the first conductivity region, the semiconductor nanostructures 202, such as including GeSn, can form oxide layers, such as including GeSnO₂. Wet etching can be used to selectively remove germanium, transforming GeSiO₂ to SiO₂ and GeSnO₂ to SnO₂. This process can increases oxygen concentration, optimizing the electrical properties and creating a gradient for dipole formation. The difference in oxygen concentration between oxide layers 231 and dipole layers 232 can enhance the distinction between P-dipoles (NFETs) and N-dipoles (PFETs), allowing for effective threshold voltage control and improved transistor performance. The dipole layers 232 can be formed from materials like In₂O₃, CeO₂, Sc₂O₃, and MgO, which can provide an oxygen density between that of SiO₂ and SnO₂, ensuring a suitable electric dipole effect.

Subsequently, gate dielectric layers 233 can be formed over the dipole layers 132, followed by gate electrode layers 234. A planarization process, such as CMP, can be performed to remove the excess dipole layer 232, the excess gate dielectric layer 133, and the excess gate electrode layer 234 until the isolation structures 250 are exposed. Therefore, the gate structures 270 can be formed to include the oxide layer 231, the dipole layer 232, the gate dielectric layer 233, and the gate electrode layer 234. The gate structures 270 can wrap around the semiconductor nanostructures 102. The combination of these layers forms effective metal gate structures for stacked NMOS/PMOS transistors TR2, contributing to enhanced device density and electrical performance. It is noted that some elements of FIG. 22 may be similar to those described with respect to FIGS. 9-12B, and thus relevant details will not be repeated for brevity.

In some embodiments, as shown in FIG. 22, the bonding structure 300 can disposed between the transistor TR1 and the transistor TR2. The bottom surface of the bonding structure 300 may be in contact with the spacers 115, the isolation structures 150, and the hard masks HM1. The top surface of the bonding structure 300 may be in contact with the gate structures 270, the inner spacers 216, and the epitaxial source/drain regions 240.

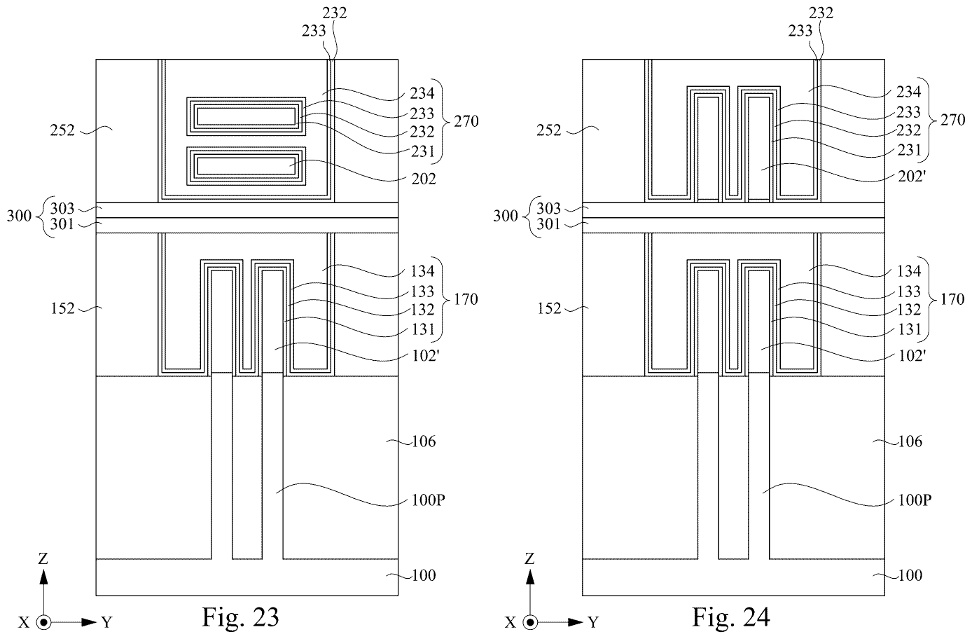

Reference is made to FIGS. 23-25. FIGS. 23-25 illustrate various configurations in which different types of transistors are bonded together, focusing on the versatility and adaptability of semiconductor manufacturing techniques, utilizing a method involving the use of metal oxide as a bipolar dipole material to enable germanium-based (Ge-based) channel CMOS technology, effectively implementing a dipole-first scheme for precise threshold voltage (Vt) control. FIGS. 23-25 illustrate cross-sectional views corresponding to cross-sectional views obtained from reference cross-sections C-C′ in FIG. 1A. The method shown in FIGS. 23-25 can include leverage metal oxide as a bipolar dipole material, which can provide an improvement in managing threshold voltages in semiconductor devices. Specifically, this approach can include Ge-based CMOS, as it can enable efficient dipole formation without the need for high-temperature processes that could otherwise degrade the channel material such that this dipole-first scheme can facilitate enhanced Vt control. In addition, the present disclosure may repeat reference numerals and/or letters in the various examples. This repetition is for the purpose of simplicity and clarity and does not in itself dictate a relationship between the various embodiments and/or configurations discussed.

Specifically, FIGS. 23-25 illustrate bonded transistors that can vary in type, including but not limited to metal-oxide-semiconductor field-effect transistors (MOSFETs), complementary metal-oxide-semiconductor (CMOS) transistors, p-channel metal-oxide semiconductors (PMOS), n-channel metal-oxide semiconductors (NMOS), bipolar junction transistors (BJTs), high-voltage transistors, high-frequency transistors, p-channel and/or n-channel field-effect transistors (PFETs/NFETs), FinFETs, planar MOS transistors with raised source/drains, nanosheet FETs, nanowire FETs, and thin-film transistors (TFTs), or other similar semiconductor devices. The flexibility in combining different types of transistors provides significant design advantages.

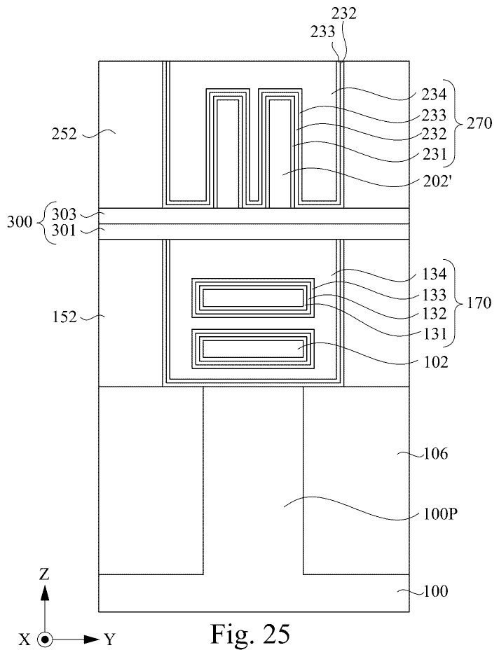

For instance, FIG. 23 illustrates a configuration where the lower device can be a FinFET while the upper device can be a nanosheet FET. That is, the channel region 102′ for the lower device can be a fin-like pattern. This configuration can leverage the benefits of both FinFETs, known for their robust control over short-channel effects, and nanosheet FETs, which provide a higher drive current and improved electrostatic control. FIG. 24 illustrates a configuration where both the lower and upper devices can be FinFETs. That is, the channel regions 102′ and 202′ for the lower and upper devices can be fin-like patterns. This configuration can achieve consistency in device characteristics for applications requiring tightly matched transistor performance. FIG. 25 illustrates a configuration where the lower device can be a nanosheet FET, while the upper device can be a FinFET. That is, the channel region 202′ for the upper device can be a fin-like pattern. This configuration can optimize the performance by utilizing nanosheet FETs for their superior channel control and FinFETs for their established manufacturing reliability and maturity. This approach of stacking different types of transistors in a vertically integrated structure not only can enhance device density but also provide the flexibility to tailor the transistor properties to specific circuit requirements.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method by using metal oxide as a bipolar dipole material to enable the use of Ge-based channel CMOS technology with an effective dipole-first scheme for VT control. Specifically, a dipole-first scheme can provide a low-temperature approach suitable for Ge-based CMOS. Additionally, the dipole-first scheme can eliminate additional drive-in and strip processes. In some embodiments, this disclosure can utilize strained GeSi and GeSn channels, which can provide a high-performance to CMOS devices.

In some embodiments, a method includes forming a germanium-based nanostructure over a substrate; forming epitaxial source/drain structures on opposite sides of the germanium-based nanostructure; forming an oxide layer wrapping around the germanium-based nanostructure; forming a oxygen-containing dipole layer over the oxide layer; forming a gate dielectric layer over the oxygen-containing dipole layer; forming a gate electrode layer over the gate dielectric layer. In some embodiments, the method further includes prior to forming the epitaxial source/drain structures, replacing the substrate with a bonding layer; and bonding the germanium-based nanostructure to a device substrate through the bonding layer. In some embodiments, the method further includes performing a removal process on the oxide layer to selective remove a germanium component in the oxide layer. In some embodiments, the germanium-based nanostructure comprises germanium silicon or germanium tin. In some embodiments, an oxygen areal density of the oxygen-containing dipole layer is different than the oxide layer. In some embodiments, an oxygen areal density of the oxygen-containing dipole layer is greater than an oxygen areal density of silicon oxide. In some embodiments, the oxygen-containing dipole layer is made of metal oxide. In some embodiments, the oxygen-containing dipole layer comprises SiO₂, In₂O₃, CeO₂, Sc₂O₃, MgO, SnO₂, or combinations thereof. In some embodiments, the oxygen-containing dipole layer is made of a material different then the gate dielectric layer. In some embodiments, the oxygen-containing dipole layer is thinner than the gate dielectric layer.

In some embodiments, a method includes forming a first channel layer over a substrate, and a second channel layer over the substrate, wherein the second channel layer is made of a different material than the first channel layer; forming a first oxide layer wrapping around the first channel layer, and a second oxide layer wrapping around the second channel layer, wherein the first oxide layer has a first oxygen areal density, and the second oxide layer has a second oxygen areal density different than the first oxygen areal density; forming a first metal oxide layer over the first oxide layer, and a second metal oxide layer over the second oxide layer, wherein the second metal oxide layer is made of a same material as the first metal oxide layer, and an oxygen areal density of the first and second metal oxide layers is between the first and second oxygen areal densities; forming a first gate dielectric layer over the first metal oxide layer, and a second gate dielectric layer over the first metal oxide layer; forming a first gate electrode layer over the first gate dielectric layer, and a second gate electrode layer over the second gate dielectric layer. In some embodiments, a NMOS transistor is composed of the first channel layer, the first oxide layer, the first metal oxide layer, the first gate dielectric layer, and the first gate electrode layer, and a PMOS transistor is composed of the second channel layer, the second oxide layer, the second metal oxide layer, the second gate dielectric layer, and the second gate electrode layer. In some embodiments, the oxygen areal density of the first metal oxide layer is higher than the first oxygen areal density of the first oxide layer. In some embodiments, the oxygen areal density of the second metal oxide layer is lower than the second oxygen areal density of the second oxide layer. In some embodiments, forming the first metal oxide layer and forming the second metal oxide layer are performed simultaneously.

In some embodiments, a semiconductor structure includes a n-type metal-oxide-semiconductor field-effect transistor (NMOSFET), a bonding layer, and a p-type MOSFET (PMOSFET). The NMOSFET includes a first channel layer, a first oxide layer over the first channel layer, a first dipole layer over the first oxide layer, wherein an oxygen areal density of the first dipole layer is higher than an oxygen areal density of the first oxide layer, a first high-k gate dielectric layer over the first dipole layer, and a first gate electrode layer over the first high-k gate dielectric layer. The bonding layer is over the NMOSFET. The PMOSFET is over the bonding layer. The PMOSFET includes a second channel layer, a second oxide layer over the first channel layer, a second dipole layer over the first oxide layer, wherein an oxygen areal density of the second dipole layer is lower than an oxygen areal density of the second oxide layer, a second high-k gate dielectric layer over the second dipole layer, and a second gate electrode layer over the second high-k gate dielectric layer. In some embodiments, the first and second channel layers comprise germanium. In some embodiments, the oxygen areal density of the first dipole layer is lower than the oxygen areal density of the second oxide layer. In some embodiments, the first dipole layer is made of a same material as the second dipole layer. In some embodiments, the first oxide layer is made of a different material than the second oxide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a germanium-based nanostructure over a substrate;
forming epitaxial source/drain structures on opposite sides of the germanium-based nanostructure;
forming an oxide layer wrapping around the germanium-based nanostructure;
forming a oxygen-containing dipole layer over the oxide layer;
forming a gate dielectric layer over the oxygen-containing dipole layer; and
forming a gate electrode layer over the gate dielectric layer.

2. The method of claim 1, further comprising:
prior to forming the epitaxial source/drain structures, replacing the substrate with a bonding layer; and
bonding the germanium-based nanostructure to a device substrate through the bonding layer.

3. The method of claim 1, further comprising:
performing a removal process on the oxide layer to selective remove a germanium component in the oxide layer.

4. The method of claim 1, wherein the germanium-based nanostructure comprises germanium silicon or germanium tin.

5. The method of claim 1, wherein an oxygen areal density of the oxygen-containing dipole layer is different than the oxide layer.

6. The method of claim 1, wherein an oxygen areal density of the oxygen-containing dipole layer is greater than an oxygen areal density of silicon oxide.

7. The method of claim 1, wherein the oxygen-containing dipole layer is made of metal oxide.

8. The method of claim 1, wherein the oxygen-containing dipole layer comprises SiO2, In2O3, CeO2, Sc2O3, MgO, SnO2, or combinations thereof.

9. The method of claim 1, wherein the oxygen-containing dipole layer is made of a material different then the gate dielectric layer.

10. The method of claim 1, wherein the oxygen-containing dipole layer is thinner than the gate dielectric layer.

11. A method, comprising:
forming a first channel layer over a substrate, and a second channel layer over the substrate, wherein the second channel layer is made of a different material than the first channel layer;
forming a first oxide layer wrapping around the first channel layer, and a second oxide layer wrapping around the second channel layer, wherein the first oxide layer has a first oxygen areal density, and the second oxide layer has a second oxygen areal density different than the first oxygen areal density;
forming a first metal oxide layer over the first oxide layer, and a second metal oxide layer over the second oxide layer, wherein the second metal oxide layer is made of a same material as the first metal oxide layer, and an oxygen areal density of the first and second metal oxide layers is between the first and second oxygen areal densities;
forming a first gate dielectric layer over the first metal oxide layer, and a second gate dielectric layer over the first metal oxide layer; and
forming a first gate electrode layer over the first gate dielectric layer, and a second gate electrode layer over the second gate dielectric layer.

12. The method of claim 11, wherein a NMOS transistor is composed of the first channel layer, the first oxide layer, the first metal oxide layer, the first gate dielectric layer, and the first gate electrode layer, and a PMOS transistor is composed of the second channel layer, the second oxide layer, the second metal oxide layer, the second gate dielectric layer, and the second gate electrode layer.

13. The method of claim 12, wherein the oxygen areal density of the first metal oxide layer is higher than the first oxygen areal density of the first oxide layer.

14. The method of claim 12, wherein the oxygen areal density of the second metal oxide layer is lower than the second oxygen areal density of the second oxide layer.

15. The method of claim 11, wherein forming the first metal oxide layer and forming the second metal oxide layer are performed simultaneously.

16. A semiconductor structure, comprising:
a n-type metal-oxide-semiconductor field-effect transistor (NMOSFET), comprising:
a first channel layer;
a first oxide layer over the first channel layer;
a first dipole layer over the first oxide layer, wherein an oxygen areal density of the first dipole layer is higher than an oxygen areal density of the first oxide layer;
a first high-k gate dielectric layer over the first dipole layer; and
a first gate electrode layer over the first high-k gate dielectric layer;
a bonding layer over the NMOSFET; and
a p-type MOSFET (PMOSFET) over the bonding layer, the PMOSFET comprising:
a second channel layer;
a second oxide layer over the first channel layer;
a second dipole layer over the first oxide layer, wherein an oxygen areal density of the second dipole layer is lower than an oxygen areal density of the second oxide layer;
a second high-k gate dielectric layer over the second dipole layer; and
a second gate electrode layer over the second high-k gate dielectric layer.

17. The semiconductor structure of claim 16, wherein the first and second channel layers comprise germanium.

18. The semiconductor structure of claim 16, wherein the oxygen areal density of the first dipole layer is lower than the oxygen areal density of the second oxide layer.

19. The semiconductor structure of claim 16, wherein the first dipole layer is made of a same material as the second dipole layer.

20. The semiconductor structure of claim 16, wherein the first oxide layer is made of a different material than the second oxide layer.
